(19) United States
(12) Patent Application Publication
(10) Pub. No.: US 2003/0042618 A1
(43) Pub. Date: Mar. 6, 2003

(54) Semiconductor device and a method of manufacturing the same

(75) Inventors: Fujiaki Nose, Ome (JP); Tomo Shimizu, Ayase (JP); Hiroshi Kikuchi, Hidaka (JP); Junichi Koike, Akishima (JP); Masataka Murata, Yokohama (JP)

Correspondence Address: MILES & STOCKBRIDGE PC, 1751 PINNACLE DRIVE, SUITE 500, MCLEAN, VA, 22102-3833, US

(73) Assignee: Hitachi, Ltd.

(21) Appl. No.: 10/195,493

(22) Filed: Jul. 16, 2002

(30) Foreign Application Priority Data
Aug. 29, 2001 (JP) 2001-259864

(51) Int. Cl. H01L 23/12; H01L 23/10; H01L 23/48; H01L 23/52; H01L 29/40

(52) U.S. Cl. 257/778; 257/710; 257/704; 257/737; 257/738

(57) ABSTRACT

In connection with a semiconductor device which adopts the face down mounting method, it is intended to provide a technique which can check the state of continuity between electrode pads formed on a semiconductor chip and electrode pads formed on a wiring substrate. The semiconductor device comprises a semiconductor chip, the semiconductor chip having a plurality of first electrode pads arranged on one main surface thereof and a first electrode pad for inspection disposed on the one main surface, a wiring substrate, the wiring substrate having a plurality of second electrode pads arranged on one main surface thereof correspondingly to the plural first electrode pads and a second electrode pad for inspection disposed on the one main surface correspondingly to the first electrode pad for inspection, and connecting means interposed between the plural first electrode pads/the first electrode pad for inspection and the plural second electrode pads/the second electrode pad for inspection to provide electrical connections therebetween.

### BACKGROUND OF THE INVENTION

The present invention relates to a semiconductor device and a technique for manufacturing the same. Particularly, the invention is concerned with a semiconductor device which adopts a face-down mounting and a technique which is applicable effectively to the manufacture of the semiconductor device.

As a technique for mounting a semiconductor chip directly onto a wiring substrate there is known, for example, a mounting technique called a face down mounting technique. According to the face down mounting technique, a semiconductor chip is mounted on a wiring substrate in a state in which one main surface as a circuit forming surface of the semiconductor chip confronts the wiring substrate.

In connection with the face down mounting technique, various mounting methods have been proposed and put to practical use. As typical methods among them, for example methods called CCB (Controlled Collapse Bonding) mounting and ACF (Anisotropic Conductive Film) have been adoped practically.

In the CCB mounting method there is used a semiconductor chip in which solder bumps formed of a metallic material having a composition of, for example, lead (Pb)-tin (Sn) are arranged as conductive bumps (salient electrodes) on electrode pads formed on one main surface of the chip, and then the solder bumps are melted to mount the semiconductor chip onto a wiring substrate. In this case, the electrode pads arranged on the one main surface of the semiconductor chip and electrode pads arranged on one main surface of the wiring substrate are connected together electrically and mechanically through the solder bumps interposed between them.

In the CCB mounting method, since the electrode pads on the semiconductor chip and the electrode pads on the wiring substrate are fixed together through solder bumps, a thermal stress induced by a difference in thermal expansion coefficient between the semiconductor chip and the wiring substrate concentrates on the solder bumps, and due to this thermal stress there easily occurs an inconvenience such as breakage of the solder bumps. Therefore, in connection with the CCB mounting method there is adopted a technique such that an insulating resin called underfill resin is filled between the wiring substrate and the semiconductor chip after mounting of the chip onto the wiring substrate to reinforce the mechanical strength of the solder bumps by the mechanical strength of the underfill resin. This technique and the CCB mounting method are described, for example, in “Electronic Materials” published by Industrial Research Association [1996, April Number, pp. 14 to 191.

In the ACF mounting method, there is used a semiconductor chip wherein stud bumps formed of, for example, gold (Au) as a main component are arranged as conductive bumps on electrode pads formed on one main surface of the chip, and the semiconductor chip is compression-bonded to a wiring substrate under heating while anisotropic conductive resin film (ACF) as an adhesive resin is interposed between the wiring substrate and the semiconductor chip, thereby mounting the semiconductor chip onto the wiring substrate. The anisotropic conductive resin is obtained by forming an insulating resin with many conductive particles dispersed and mixed therein into a sheet. For example, a thermosetting epoxy resin is used as the insulating resin. The stud bumps formed of Au as a main component are obtained by melting tips of Au wires to form balls, then thermocompression-bonding the balls to the electrode pads on one main surface of the semiconductor chip under ultrasonic oscillation, and subsequently separating the ball portions from the Au wires. The ACF method is described in, for example, Japanese Published Unexamined Patent Application Nos. Hei 4 (1992)-345041 and Hei 5 (1993)-175280.

As mounting methods involving thermocompression bonding of a semiconductor chip there are known, in addition to the ACF mounting method, an NCF mounting method which uses, as an adhesive resin, an insulating resin film (NCF: Non Conductive Film) with conductive particles not incorporated therein and an ACP mounting method which uses a paste-like anisotropic conductive resin (ACP: Anisotropic Conductive Paste).

Also known is a mounting method (hereinafter referred to as the “bumpless mounting method”) in which conductive bumps are omitted and a semiconductor chip is mounted onto a wiring substrate with use of an anisotropic conductive resin. The bumpless mounting method is described, for example, in Japanese Patent Published Unexamined Patent Application No. Hei 8(1996)-115949.

### SUMMARY OF THE INVENTION

The face down mounting method permits a semiconductor chip to be mounted within the area of the semiconductor chip and is therefore useful in attaining the reduction in size of the associated semiconducor device as compared with a face up mounting method wherein electrode pads on a semiconductor chip and electrode pads on a wiring substrate are connected together electrically through bonding wires. Besides, since the face down mounting method permits the reduction in size of a signal propagation path between electrodes pads on the semiconductor chip and the wiring substrate, it is effective in attaining the speed-up of the semiconductor device.

In the face down mounting method, however, since the electrode pads on the semiconductor chip and the electrode pads on the wiring substrate are disposed between the chip and the substrate, it is difficult to check the state of continuity of between both electrode pads by visual inspection.

Moreover, the inspection for the state of continuity between the electrode pads on the semiconductor chip and the electrode pads on the wiring substrate is conducted in a performance test in a final selection step, so even if the state of continuity between both electrode pads is defective at the stage of mounting the semiconductor chip, it is impossible to confirm the defect until a final inspection step is conducted. Thus, even for a defective product involving a defective continuity between the electrode pads on the semiconductor chip and the electrode pads on the wiring substrate, there are conducted various steps which lie between the chip mounting step and the final inspection step, with consequent increase in cost of the semiconductor device.

It is an object of the present invention to provide a technique which permits inspection of the state of continuity between electrode pads on a semiconductor chip and electrode pads on a wiring substrate in a semiconductor device adopting the face down mounting method.

It is another object of the present invention to provide a technique which can reduce the cost of a semiconductor device adopting the face down mounting method.

The above and other objects and novel features of the present invention will become apparent from the following description and the accompanying drawings.

Typical inventions disclosed herein will be outlined below.

(1) A semiconductor device comprising:

a semiconductor chip having a plurality of first electrode pads arranged on one main surface thereof and a first electrode pad for inspection disposed on the one main surface;

a wiring substrate having a plurality of second electrode pads arranged on one main surface thereof correspondingly to the plural first electrode pads and a second electrode pad for inspection disposed on the one main surface correspondingly to the first electrode pad for inspection; and

connecting means interposed between the plural first electrode pads/the first electrode pad for inspection and the plural second electrode pads/the second electrode pad for inspection to provide electrical connections therebetween.

(2) A semiconductor device as set forth in the above means (1), further comprising a third electrode pad for inspection connected electrically to the first electrode pad for inspection and a fourth electrode pad for inspection connected electrically to the second electrode pad for inspection, the third and fourth electrode pads for inspection being formed on the wiring substrate.

(3) A semiconductor device as set forth in the above means (2), wherein the third and fourth electrode pads for inspection are arranged on one main surface of the wiring substrate and periphery of the semiconductor chip.

(4) A semiconductor device as set forth in the above means (2), wherein the first, second, third, and fourth electrode pads are connected in series.

(5) A semiconductor device as set forth in the above means (2), wherein the first, second, third, and fourth electrode pads for inspection are electrically separated from the plural first and second electrode pads.

(6) A semiconductor device as set forth in the above means (1), wherein the one main surface of the semiconductor chip is formed in a quadrangular shape, and the first electrode pad for inspection is disposed at a corner of the semiconductor chip.

(7) A semiconductor device as set forth in the above means (1), wherein the connecting means are conductive bumps.

(8) A semiconductor device as set forth in the above means (1), wherein the connecting means are constituted by an anisotropic conductive resin comprising an insulating resin and a plurality of conductive particles mixed therein.

(9) A semiconductor device as set forth in the above means (1), wherein the connecting means comprise conductive bumps and an anisotropic conductive resin comprising an insulating resin and a plurality of conductive particles incorporated therein.

(10) A semiconductor device as set forth in the above means (1), wherein the wiring substrate further has a plurality of third electrode pads on another main surface thereof opposite to the one main surface thereof, the plural third electrode pads being electrically connected to the plural second electrode pads respectively.

(11) A semiconductor device as set forth in the above means (1), wherein the semiconductor chip further has an integrated circuit, the plural first electrode pads are electrically connected to the integrated circuit, and the first electrode pad for inspection is electrically separated from the integrated circuit.

(12) A method of manufacturing a semiconductor device, comprising the steps of:

(a) providing a semiconductor chip having on one main surface thereof a plurality of first electrode pads and a first electrode pad for inspection, and providing a wiring substrate having on one main surface thereof a plurality of second electrode pads arranged correspondingly to the plural first electrode pads and a second electrode pad for inspection disposed correspondingly to the first electrode pad for inspection;

(b) interposing conductive patterns between the plural first electrode pads/the first electrode pad for inspection and the plural second electrode pads/the second electrode pad for inspection to provide electrical connections therebetween;

(c) applying a voltage between the first and second electrodes pads for inspection to check the state of continuity between the two; and

(d) filling an insulating resin between the one main surface of the semiconductor chip and the one main surface of the wiring substrate,

wherein the step (c) is carried out after the step (b) and before the step (d).

### BRIEF DESCRIPTION OF THE DRAWINGS

FIG. 1 is a schematic plan view showing a schematic construction of a semiconductor device according to a first embodiment of the present invention;

FIG. 2 is a schematic sectional view of the semiconductor device of the first embodiment;

FIG. 3 is a partially enlarged schematic sectional view of FIG. 2;

FIG. 4 is a schematic plan view showing a state of connection in the semiconductor device of the first embodiment;

FIG. 5 is a schematic plan view showing a schematic construction of a wiring substrate used in the semiconductor device of the first embodiment;

FIG. 6 is a schematic plan view showing a schematic construction of a semiconductor chip used in the semiconductor device of the first embodiment;

FIG. 7 is a schematic sectional view showing a schematic construction of the semiconductor chip;

FIG. 8 is a process flow chart for explaining the manufacture of the semiconductor device of the first embodiment;

FIGS. 9(a) to 9(d) are schematic sectional views in various steps corresponding to FIG. 8;

FIG. 10 is a schematic plan view showing a state of connection in a semiconductor device according to a second embodiment of the present invention;

FIG. 11 is a schematic sectional view of a semiconductor device according to a third embodiment of the present invention;

FIG. 12 is a schematic sectional view of a semiconductor chip according to a fourth embodiment of the present invention; and

FIG. 13 is a schematic sectional view of a semiconductor device according to a fifth embodiment of the present invention.

### DETAILED DESCRIPTION OF THE PREFERRED EMBODIMENTS

Embodiments of the present invention will be described in detail hereinunder with reference to the accompanying drawings. In all of the drawings illustrative of the embodiments, portions having the same functions are identified by the same reference numerals and repeated explanations thereof will be omitted.

(First Embodiment)

In this embodiment, a description will be given below about an example in which the present invention is applied to a semiconductor device adopting the CCB method.

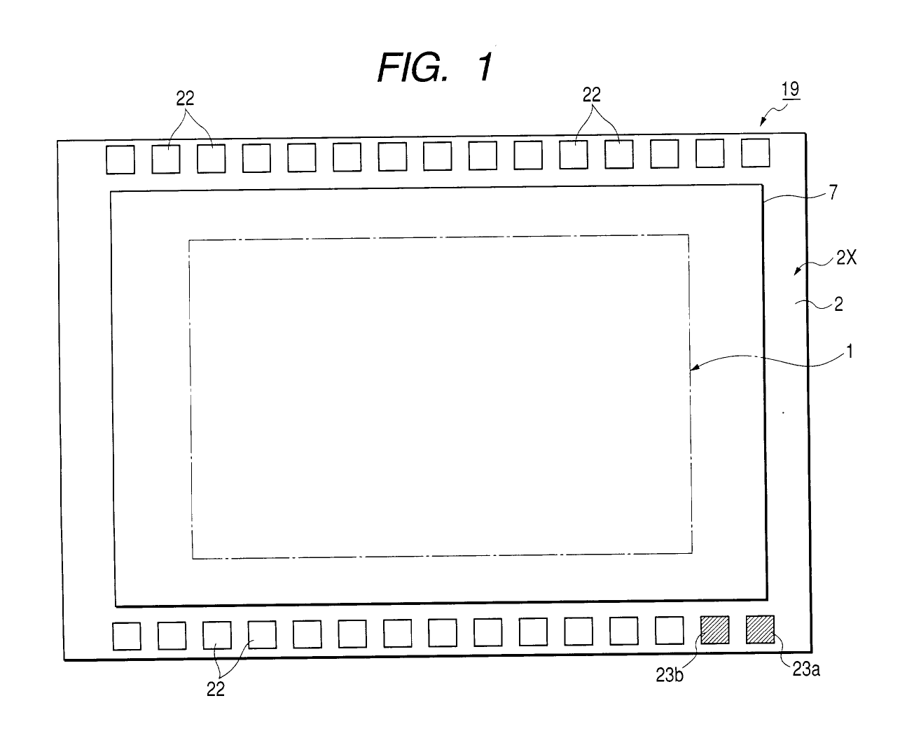

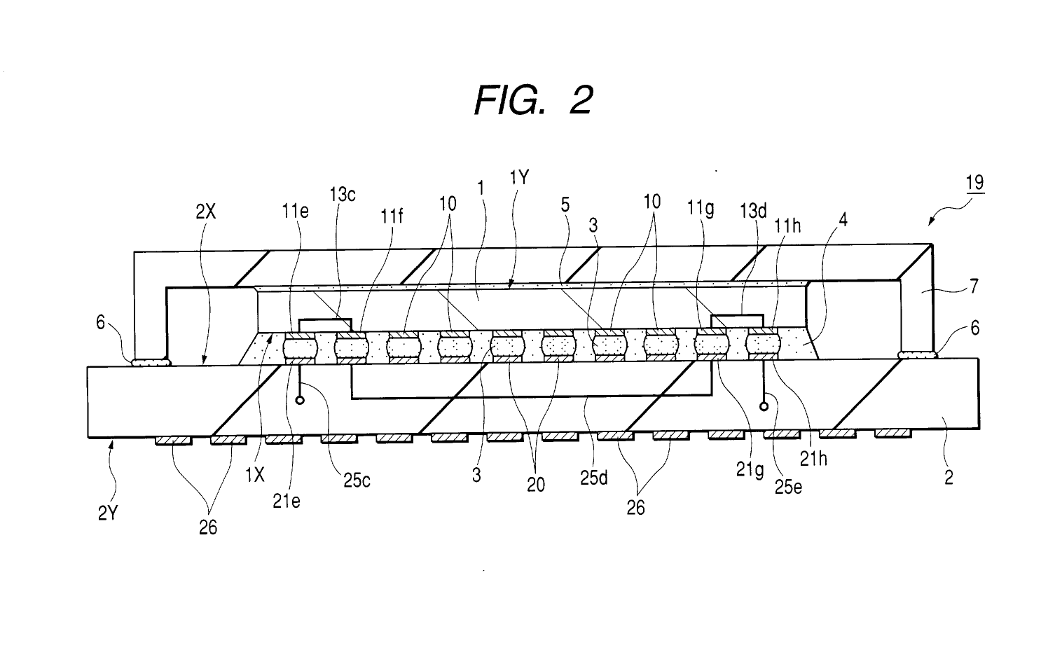

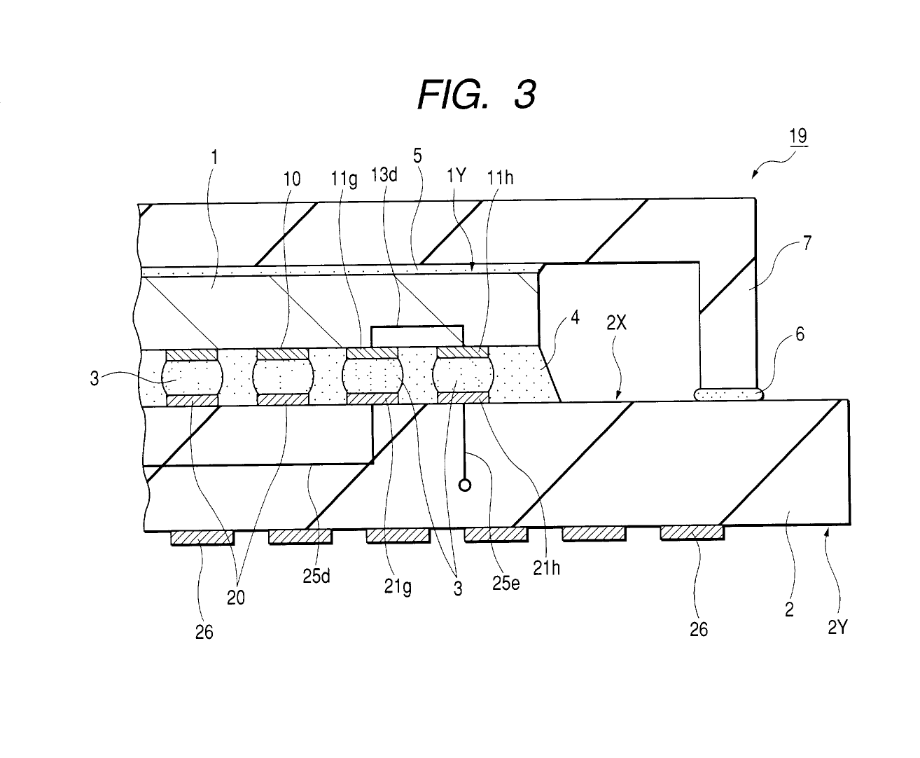

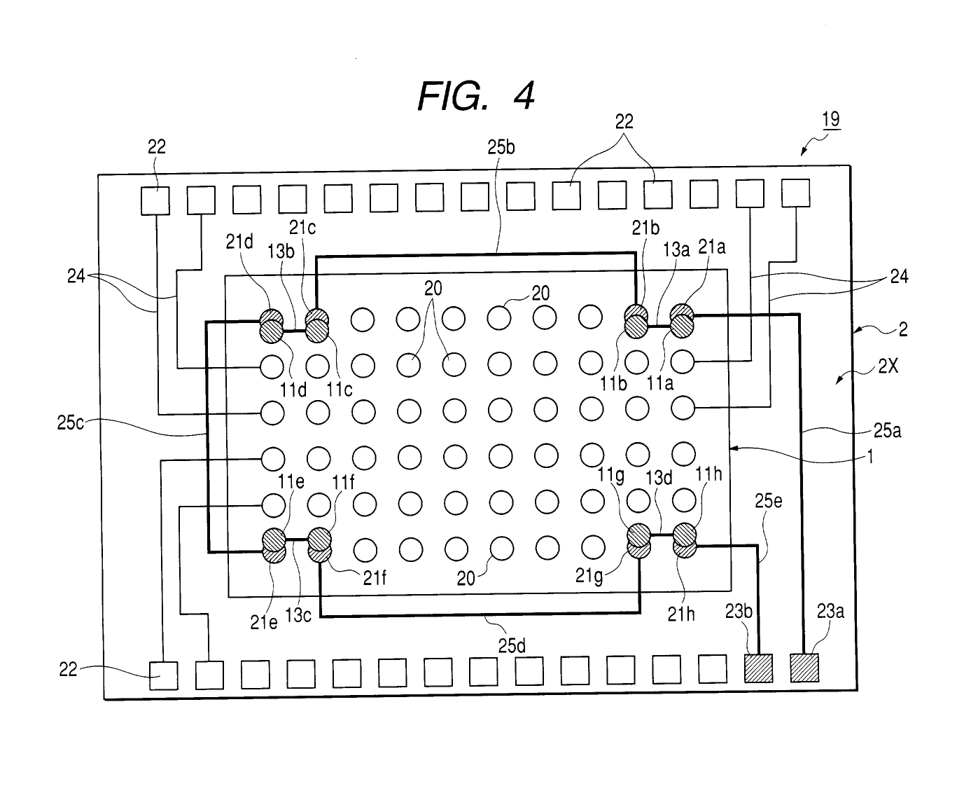

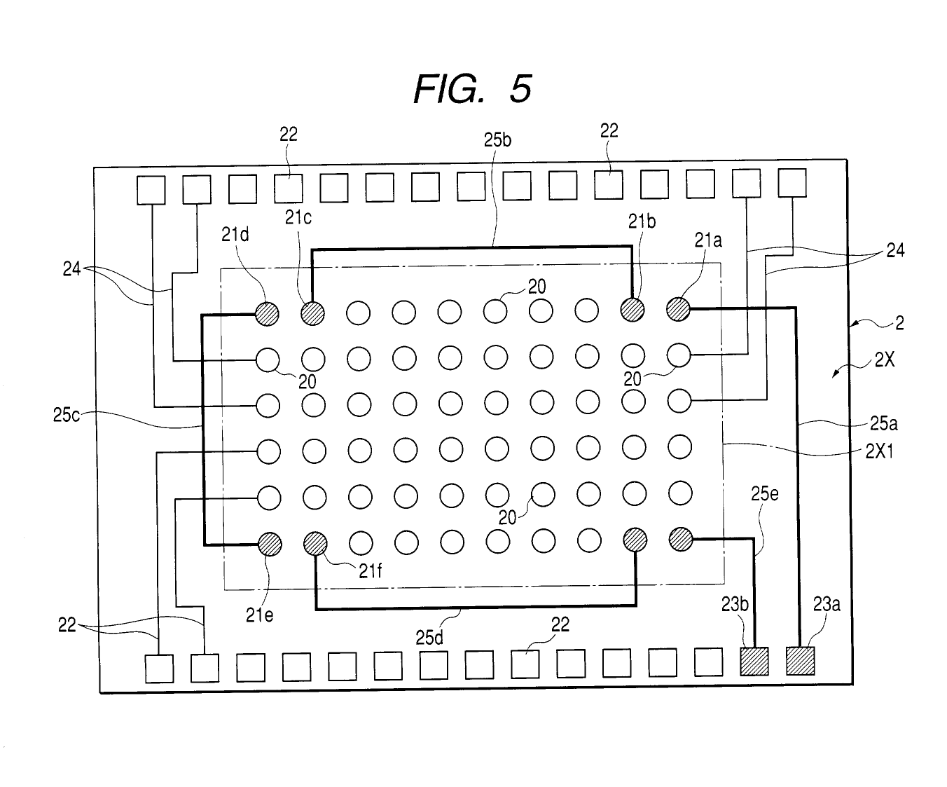

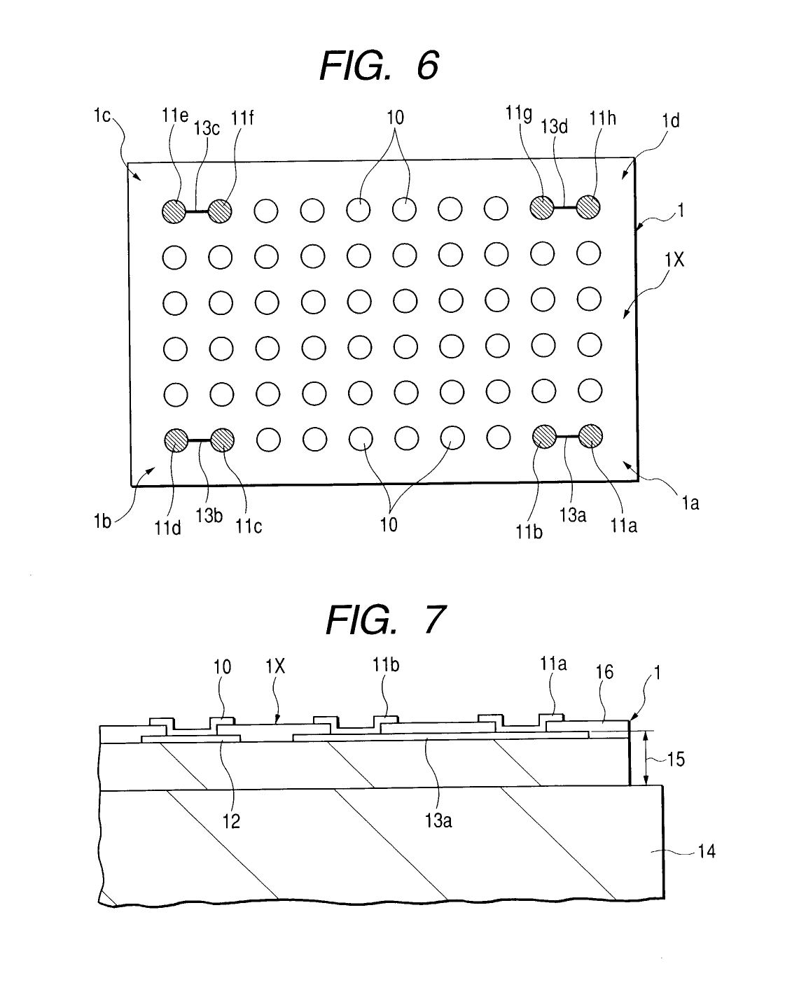

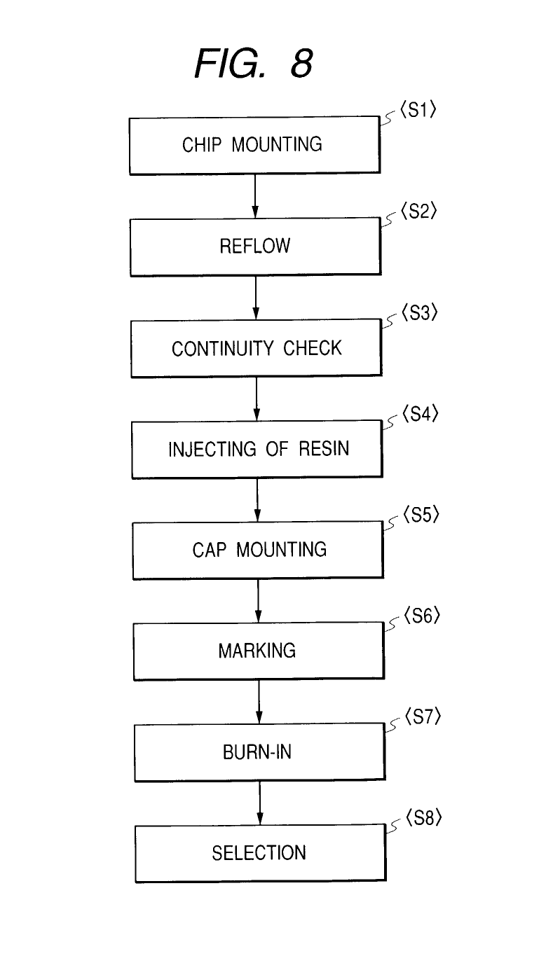

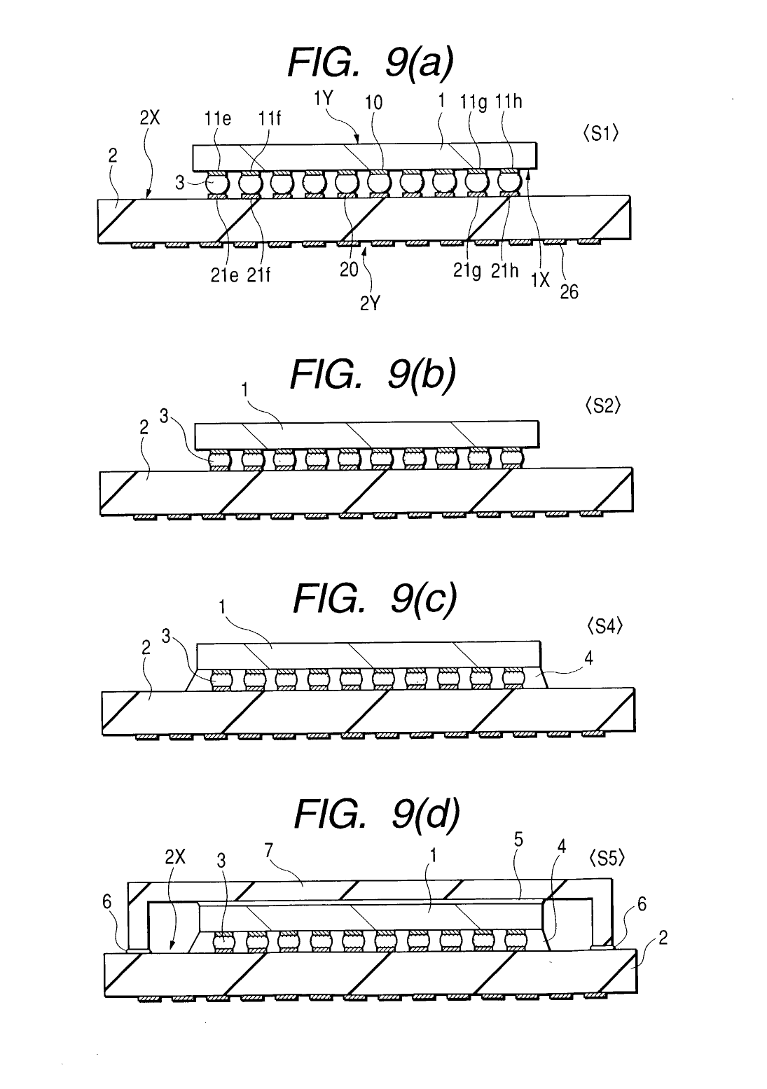

FIG. 1 is a schematic plan view showing a schematic construction of a semiconductor device according to a first embodiment of the present invention, FIG. 2 is a schematic sectional view of the semiconductor device of the first embodiment, FIG. 3 is a partially enlarged schematic sectional view of FIG. 2, FIG. 4 is a schematic plan view showing a state of connection in the semiconductor device of the first embodiment, FIG. 5 is a schematic plan view showing a schematic construction of a wiring substrate used in the semiconductor device of the first embodiment, FIG. 6 is a schematic plan view showing a schematic configuration of a semiconductor chip used in the semiconductor device of the first embodiment, FIG. 7 is a schematic sectional view showing a schematic construction of the semiconductor chip, FIG. 8 is a process flow chart for explaining the manufacture of the semiconductor device of the first embodiment, and FIGS. 9(a) to 9(d) are schematic sectional views in various steps corresponding to FIG. 8.

As shown in FIGS. 1 to 3, a semiconductor device 19 according to a first embodiment of the present invention has a package structure such that a semiconductor chip 1 is sealed within a cavity formed by a wiring substrate 2 and a sealing cap 7.

The semiconductor chip 1 has one main surface (a circuit forming surface) 1X and a rear surface (another main surface) 1Y opposed to each other, the one main surface 1X and the rear surface 1Y being formed in a quadrangular shape. In this embodiment, the semiconductor chip 1 is formed in a rectangular shape in plan.

As shown in FIGS. 6 and 7, the semiconductor chip 1 mainly comprises, though no limitation is made to this construction, a semiconductor substrate 14, plural semiconductor elements formed on one main surface of the semiconductor substrate 14, a multi-layer interconnection 15 formed on the one main surface of the semiconductor substrate 14, the multi-layer interconnection being constituted by a stack of plural stages of insulating layers and wiring layers, and a surface protecting film (final protecting film) 16 formed so as to cover the multi-layer interconnection 15. For example, the semiconductor substrate 14 is formed of a single crystal silicon, the multi-layer interconnection 15 is formed by a silicon oxide film, and the wiring layers in the multi-layer interconnection 15 are each formed by a conductive film of copper (Cu) or Cu alloy containing Cu as a main component. The surface protecting film is formed, for example, by an insulating film or an organic insulating film, e.g. a silicon oxide or silicon nitride film.

On one main surface 1X of the semiconductor chip 1 are arranged plural electrode pads 10 and eight electrode pads for inspection (11a to 11h). Further, on one main surface 1X side of the semiconductor chip is formed a system circuit as an integrated circuit, with, for example, both a memory circuit and a logical operation circuit formed thereon. The system circuit is constituted by plural semiconductor elements formed on the semiconductor substrate 14 and plural wiring lines formed on the multilayer interconnection 15.

The plural electrode pads 10 and eight electrode pads (11a to 11h) for inspection are arranged in a matrix form, constituting a group of pads. The plural electrode pads 10 are electrically connected through apertures formed in the surface protecting film 16 to plural wiring lines 12 formed in a top wiring layer of the multi-layer interconnection 15.

The electrode pads 11a for inspection are electrically connected through an aperture formed in the surface protecting film 16 to one end side of a wiring line 13a formed in the top wiring layer of the multi-layer interconnection 15, while the electrode pad 11b for inspection is electrically connected to an opposite end side of the wiring line 13a through an aperture formed in the surface protecting film 16. The electrode pad 11c for inspection is electrically connected through an aperture formed in the surface protecting film 16 to one end side of a wiring line 13b formed in the top wiring layer of the multi-layer interconnection 15, while the electrode pad 11d for inspection is electrically connected to an opposite end side of the wiring line 13b through an aperture formed in the surface protecting film 16. The electrode pad 11e for inspection is electrically connected through an aperture formed in the surface protecting film 16 to one end side of a wiring line 13c formed in the top wiring layer of the multi-layer interconnection 15, while the electrode pad 11f for inspection is electrically connected to an opposite end side of the wiring line 13c through an aperture formed in the surface protecting film 16. The electrode pad 11g for inspection is electrically connected through an aperture formed in the surface protecting layer 16 to one end side of a wiring line 13d formed in the top wiring layer of the multi-layer inter connection 15, while the electrode pad 11h for inspection is electrically connected to an opposite end side of the wiring line 13d through an aperture formed in the surface protecting film 16. Thus, as to the electrode pads for inspection, 11a and 11b, 11c and 11d, 11e and 11f, and 11g and 11h, are respectively interconnected electrically through internal wiring lines in the semiconductor chip 1.

The electrode pads 11a and 11b for inspection are disposed at a first corner 1a of the semiconductor chip 1, the electrode pads 11c and 11d for inspection are disposed at a second corner 1b of the chip, the electrode pads 11e and 11f for inspection are disposed at a third corner 1c of the chip, and the electrode pads 11g and 11h for inspection are disposed at a fourth corner 1d.

The plural electrode pads 10 are electrically connected an integrated circuit (the system circuit in this embodiment) which is incorporated in the semiconductor chip 1. The eight electrode pads for inspection (11a to 11h) are electrically isolated from the integrated circuit incorporated in the semiconductor chip 1 and also electrically isolated from the plural electrode pads 10.

As shown in FIGS. 2 and 5, the wiring substrate 2 has one main surface 2X and a rear surface (another main surface) 2Y which are opposite to each other. The one main surface 2X and the rear surface 2Y are formed in a quadrangular shape in plan. In this embodiment, the wiring substrate 2 is formed, for example, in a rectangular shape in plan. The wiring substrate 2 has a multi-layer interconnection constituted by a stack of plural insulating substrates formed of alumina for example.

On one main surface 2X of the wiring substrate 2 are arranged plural electrode pads 20 and eight electrode pads (21a to 21h) for inspection. Plural electrode pads 22 for inspection and two electrode pads (23a, 23b) for inspection are also arranged on one main surface 2X of the wiring substrate 2. Further, on one main surface 2X of the wiring substrate 2 is formed a chip mounting area 2X1 in which the semiconductor chip 1 is mounted.

The plural electrode pads 20 and eight electrode pads for inspection (21a to 21h) are arranged in a matrix form within a chip mounting area 1X1, constituting a group of pads. The plural electrode pads 20 are arranged correspondingly to the plural electrode pads 10 formed on the semiconductor chip 1, while the eight electrode pads for inspection (21a to 2h) are arranged correspondingly to the eight electrode pads for inspection (11a to 11h) formed on the semiconductor chip 1.

The plural electrode pads 20 for inspection and two electrode pads (23a, 23b) for inspection are arranged outside the chip mounting area, i.e., periphery of the semiconductor chip 1. More specifically, approximately half of the plural electrode pads 22 for inspection are arranged along one of two opposed long sides of one main surface of the wiring substrate 2, while the remaining half of the electrode pads 22 for inspection and two electrode pads (23a, 23b) for inspection are arranged along the other long side.

The electrode pad 21a for inspection is electrically connected to the electrode pad 23a for inspection through an internal wiring line 25a in the wiring substrate 2. The electrode pad 21b for inspection is electrically connected to the electrode pad 21c for inspection through an internal wiring line 25b in the wiring substrate 2. The electrode pad 21d for inspection is electrically connected to the electrode pad 21e for inspection through an internal wiring line 25c in the wiring substrate 2. The electrode pad 21f for inspection is electrically connected to the electrode pad 21g for inspection through an internal wiring line 25d in the wiring substrate 2. The electrode pad 21h for inspection is electrically connected to the electrode pad 23b for inspection through an internal wiring line 25e.

The electrode pads 21a and 21b for inspection are disposed at a first corner of the chip mounting area 2X corresponding to the first corner 1a of the semiconductor chip 1. The electrode pads 21c and 21d for inspection are disposed at a second corner of the chip mounting area 2X corresponding to the second corner 1b of the semiconductor chip 1. The electrode pads 21e and 21f for inspection are disposed at a third corner of the chip mounting area 2X corresponding to the third corner 1c of the semiconductor chip 1. The electrode pads 21g and 21h for inspection are disposed at a fourth corner of the chip mounting area 2X1 corresponding to the fourth corner 1b of the semiconductor chip 1.

The plural electrode pads 22 for inspection are electrically connected to predetermined electrode pads 20 out of plural electrode pads 20 through internal wiring lines 24 in the wiring substrate 2. The two electrode pads (23a, 23b) for inspection and eight electrode pads (21a to 21h) for inspection are electrically isolated from the plural electrode pads 20 and plural electrode pads 22 for inspection.

As shown in FIGS. 2 and 3, one main surface of the semiconductor chip 1 is disposed on and in opposition to one main surface 2X of the wiring substrate 2. Electric connections between the plural electrode pads 10 arranged on one,main surface 1X of the semiconductor chip 1 and the plural electrode pads 20 arranged on one main surface 2X of the wiring substrate 2 are provided by connecting means interposed therebetween. Likewise, electric connections between the eight electrode pads for inspection (11a to 11h) arranged on one main surface 1X of the semiconductor chip 1 and the eight electrode pads for inspection (21a to 21h) arranged on one main surface 2X of the wiring substrate 2 are provided by connecting means interposed there between. In this embodiment, solder bumps (conductive bumps) 3 are used as the connecting means. As the solder bumps there are used solder bumps formed of a conductive material (Pb-free material) with a composition of, for example, Sn (tin)−1[wt %] Ag (silver)−0.5[wt %] Cu (copper).

The plural electrode pads 10 on the semiconductor chip 1 are fixed respectively to the plural electrode pads 20 on the wiring substrate 2 through solder bumps 3. The eight electrode pads for inspection (11a to 11h) on the semiconductor chip 1 are fixed respectively to the eight electrode pads for inspection (21a to 21h) on the wiring substrate 2.

Of the electrode pads for inspection (11a to 11h) on the semiconductor chip 1 and electrode pads for inspection (21a to 21h) on the wiring substrate 2, 11a is electrically connected to 21a through solder bump 3, 11b is electrically connected to 21b through solder bump 3, 11c is electrically connected to 21c through solder bump 3, 11d is electrically connected to 21d through solder bump 3, 11e is electrically connected to 21e through solder bump 3, 11f is electrically connected to 21f through solder bump 3, 11g is electrically connected to 21g through solder bump 3, and 11h is electrically connected to 21h through solder bump 3. Thus, as shown in FIG. 4, the electrode pads for inspection, 23a, 23b, 11a to 11h, and 21a to 21h, are respectively connected in series through internal wiring lines in the semiconductor chip 1, internal wiring lines in the wiring substrate 2, and solder bumps 3.

The plural electrode pads 20 for inspection and two electrode pads (23a, 23b) for inspection are arranged outside a sealing cap 7. Prior to mounting of the semiconductor chip 1, the solder bumps 3 are formed, for example, on the electrode pads 10 and electrode pads for inspection (11a to 11h) both arranged on the semiconductor chip 1 although this does not constitute any limitation.

Underfill resin 4, which is an epoxy-based thermosetting type insulating resin, for example, is filled (injected) between the semiconductor chip 1 and the wiring substrate 2. By thus filling the underfill resin 10 between the semiconductor chip 1 and the wiring substrate 2, the mechanical strength of the solder bumps 3 can be reinforced by the mechanical strength of the underfill resin 4, so that it is possible to prevent damage of the solder bumps 3 caused by a difference in thermal expansion coefficient between the semiconductor chip 1 and the wiring substrate 2.

Plural electrode pads 26 are arranged on the rear surface 2Y of the wiring substrate 2. The plural electrode pads 26 are electrically connected respectively to the plural electrode pads 20 arranged on one main surface 2X of the wiring substrate 2. Further, the plural electrode pads 26 are arranged at a wider arrangement pitch that of the plural electrode pads 20.

The sealing cap 7 has a base portion which confronts the rear surface 1Y of the semiconductor chip 1 and leg portions which confront side faces of the semiconductor chip 1. The leg portions of the sealing cap 7 are bonded and fixed to one main surface 2X of the wiring substrate 2 through an adhesive 6 which is resin for example. The rear surface lY of the semiconductor chip 1 is connected to an inner wall surface of the sealing cap 7 through a heat transfer material 5 which is resin for example.

Next, with reference to FIGS. 8 and 9, the following description is provided about manufacturing the semiconductor device 19.

First, the semiconductor chip 1 shown in FIGS. 6 and 7 and the wiring substrate 2 shown in FIG. 5 are provided. Though not shown in FIGS. 6 and 7, solder bumps 3 are formed on the electrode pads 10 and electrode pads for inspection (11a to 11h) arranged on the semiconductor chip 1.

Then, the semiconductor chip 1 is mounted on the chip mounting area 2X1 of one main surface 2X of the wiring substrate 2 (see <S1> in FIG. 8 and FIG. 9(a)). The mounting of the semiconductor chip 1 is performed in such a manner that one main surface 1X of the semiconductor chip 1 confronts one main surface 2X of the wiring substrate 2. Further, the mounting of the semiconductor chip 1 is performed so that the electrode pads 10 on the semiconductor chip 1 and the electrode pads 20 on the wiring substrate 2 confront each other and so that the electrode pads for inspection (11a to 11h) on the semiconductor chip 1 and the electrode pads for inspection (21a to 21h) on the wiring substrate 2 confront each other. In this step, solder bumps 3 are interposed between the electrode pads 10 and 20 and also between the electrode pads for inspection (11a to 11h) and (21a to 21h).

Next, the solder bumps 3 are melted and thereafter cured to connect the electrode pads on the semiconductor chip 1 and the electrode pads 20 on the wiring substrate 2 with each other electrically and mechanically and also connect the electrode pads for inspection (11a to 11h) on the semiconductor chip 1 and the electrode pads (21a to 21h) on the wiring substrate 2 with each other electrically and mechanically (see <S2> in FIG. 8 and FIG. 9(b)).

Then, the state of continuity between the electrode pads 10 on the semiconductor chip 1 and the electrode pads 20 on the wiring substrate 2 is checked (see <S3> in FIG. 8). This test can be performed by checking the state of continuity between the electrode pads for inspection (11a to 11h) and (21a to 21h). This test is made by applying a voltage between the pads for inspection 23a and 23b. If the state of continuity between the electrode pads for inspection (11a to 11h) and the electrode pads for inspection (21a to 21h), there flows an electric current between the electrode pads for inspection 23a and 23b. In contrast therewith, if the state of continuity between the electrode pads for inspection (11a to 11h) and (21a to 21h) is bad, there flows no electric current between the electrode pads for inspection 23a and 23b. The connection between the electrode pads for inspection (11a to 11h) and (21a to 21h) is conducted at about the same conditions as in the connection between the electrode pads 10 and 20 although there are some variations. Therefore, by checking the state of continuity between the electrode pads for inspection (11a to 11h) and (21a to 21h) it is possible to check, though indirectly, the state of continuity between the electrode pads 10 on the semiconductor chip 1 and the electrode pads 20 on the wiring substrate 20.

In the case where the state of continuity between the electrode pads for inspection (11a to 11h) and (21a to 21h) is bad, the state of continuity between the electrode pads 10 and 20 can also be judged to be bad objectively. In this step, therefore, it is possible to remove defective products.

As to positional deviations between the electrode pads 10 on the semiconductor chip 1 and the electrode pads 20 on the wiring substrate 20, there occur largest positional deviations at corners of the semiconductor chip 1. Also as to such a stress as heat distortion, it is the largest at corners of the semiconductor chip 1. That is, at corners of the semiconductor chip 1 there occur a larger number of defective connections between the electrode pads 10 and 20. Therefore, by arranging the electrode pads for inspection (11a to 1h) at corners of the semiconductor chip 1, the reliability of inspection is improved.

Next, the underfill resin 4, which is an epoxy-based thermosetting type insulating resin, for example, is filled (injected) between the semiconductor chip 1 and the wiring substrate 2 and is then allowed to cure (see <S4> in FIG. 8 and FIG. 9(c)). Although a thermal stress caused by a difference in thermal coefficient between the semiconductor chip 1 and the wiring substrate 2 is concentrated on the solder bumps 3, the stress concentrated on the solder bumps 3 is dispersed by filling the underfill resin 4, thus resulting in the defect factor becoming small. Accordingly, by checking the state of continuity between the electrode pads on the semiconductor chip 1 and the electrode pads 20 on the wiring substrate 2 after mounting of the semiconductor chip and before filling the underfill resin 4 between the semiconductor chip and the wiring substrate, the reliability of inspection is improved.

Next, the sealing cap 7 is attached to one main surface 2X of the wiring substrate 2 to seal the semiconductor chip 1 (see <S5> in FIG. 8 and FIG. 9(d)). The mounting of the sealing cap 7 is performed using the adhesive 6 which is resin for example. In this step, connection between the rear surface 1 of the semiconductor chip 1 and the inner wall of the sealing cap 7 is also performed using the heat transfer material 5, which is resin for example.

Next, marks such as product number, lot number, and product name are affixed to the sealing cap 7 (<S6> in FIG. 8) and thereafter a burn-in test (aging test) is conducted (<S7> in FIG. 8. The burn-in test is an accelerative test in which a circuit operation is performed in a working condition (a loaded condition) severer than the working condition on the customer side, allowing products which will become defective during use on the customer side, defects in a certain sense, to be generated acceleratively, and it is intended to remove such defective products in an initial stage before shipment to customers. The burn-in test is conducted using plural electrode pads 22 arranged on one main surface 2X of the wiring substrate 2.

Thereafter, a selection test (<S8> in FIG. 8) is conducted, whereby the semiconductor device 19 is nearly completed.

Thus, the following effects are obtained according to this embodiment.

(1) The semiconductor device 19 comprises:

a semiconductor chip 1 having plural electrode pads 10 arranged on one main surface 1X and an electrode pad 11a for inspection disposed on one main surface 1X;

a wiring substrate 2 having plural electrode pads 20 arranged on one main surface 2X thereof correspondingly to the plural electrode pads and an electrode pad 21a for inspection disposed on the one main surface 2X correspondingly to the electrode pad 11a for inspection; and

plural solder bumps 3 as connecting means interposed between the plural electrode pads 10/electrode pad 11a for inspection and the plural electrode pads 20/electrode pad 21a for inspection to provide electrical connections therebetween.

According to this construction, by checking the state of continuity between the electrodes pads for inspection 11a and 21a, it is possible to check the state of continuity between the electrode pads 10 on the semiconductor chip 1 and the electrode pads 20 on the wiring substrate 2, thus making it possible to check the state of continuity between the electrode pads 10 and 20.

It is also possible to electrically check the state of continuity between the electrode pads 10 and 20.

Further, since the state of continuity between the electrode pads 10 on the semiconductor chip 1 and the electrode pads 20 on the wiring substrate 20 can be checked just after mounting of the semiconductor chip, a defective product which was found to be defective in the state of continuity between both such electrode pads in the chip mounting step can be eliminated in an early stage. As a result, it becomes unnecessary to perform the manufacturing steps which follow the inspection step for such defective products, whereby it is possible to reduce the cost of the semiconductor device 19.

(2) The semiconductor device 19 further comprises an electrode pad 23a for inspection connected electrically to the electrode pad 11a for inspection and an electrode pad 23a for inspection connected electrically to the electrode pad 21a for inspection, the electrode pads 23a and 23b for inspection being formed on the wiring substrate 2.

According to this construction, it is possible to easily check the state of continuity between the electrode pads 10 on the semiconductor chip 1 and the electrode pads 20 on the wiring substrate 2.

(3) The electrode pad 11a for inspection is disposed at a corner of the semiconductor chip 1.

According to this construction, the reliability of inspection is improved because the portion where the inspection is performed is a largely stressed portion.

(4) In manufacturing the semiconductor device 19, the step of checking the state of continuity between the electrode pads 11a and 21a for inspection is carried out after the step of electrically connecting the plural electrode pads 10 and the electrode pad 11a for inspection with the plural electrode pads 20 and the electrode pad 21a for inspection through solder bumps 3 and before the step of filling the underfill resin 4 between one main surface 1X of the semiconductor chip 1 and one main surface 2X of the wiring substrate 2.

By so doing, the inspection is performed before the stress concentrated on the solder bumps 3 is dispersed by filling of the underfill resin, so that the reliability of inspection is improved.

(Second Embodiment)

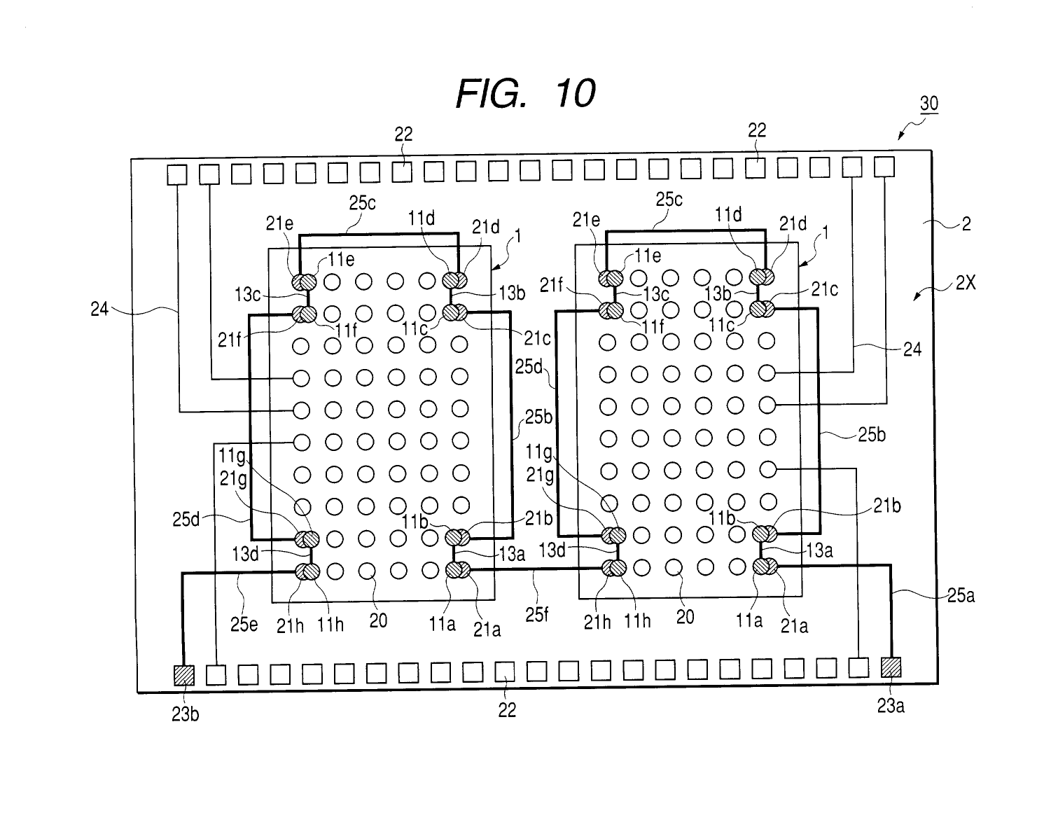

FIG. 10 is a schematic plan view showing a state of connection in a semiconductor device according to the second embodiment of the present invention.

As shown in FIG. 10, a semiconductor device 30 of this second embodiment has a construction such that two semiconductor chips 1 are mounted on one main surface 2X of a wiring substrate 2 by the CCB mounting method. Connection patterns between electrode pads for inspection formed on each semiconductor chip 1 and electrode pads for inspection formed on the wiring substrate 2 are about the same as in the previous first embodiment. A difference is recognized in that an electrode pad 21h for inspection on the wiring substrate 2, which is located on one semiconductor 1 side, is electrically connected through an internal wiring line 25f in the wiring substrate 2 to an electrode pad 21a for inspection on the wiring substrate, which is located on the other semiconductor chip 1 side.

Thus, on the wiring substrate 2, by electrically connecting the electrode pad 21h for inspection located on one semiconductor chip 1 side with the electrode pad 21a for inspection located on the other semiconductor chip 1 electrically through the internal wiring line 25f in the wiring substrate 2, electrode pads for inspection 23a, 23b, 11a to 11h, and 21a to 21h can be connected in series, so that with simple wiring patterns, it is possible to check plural portions and plural semiconductor chips 1 at a time.

(Third Embodiment)

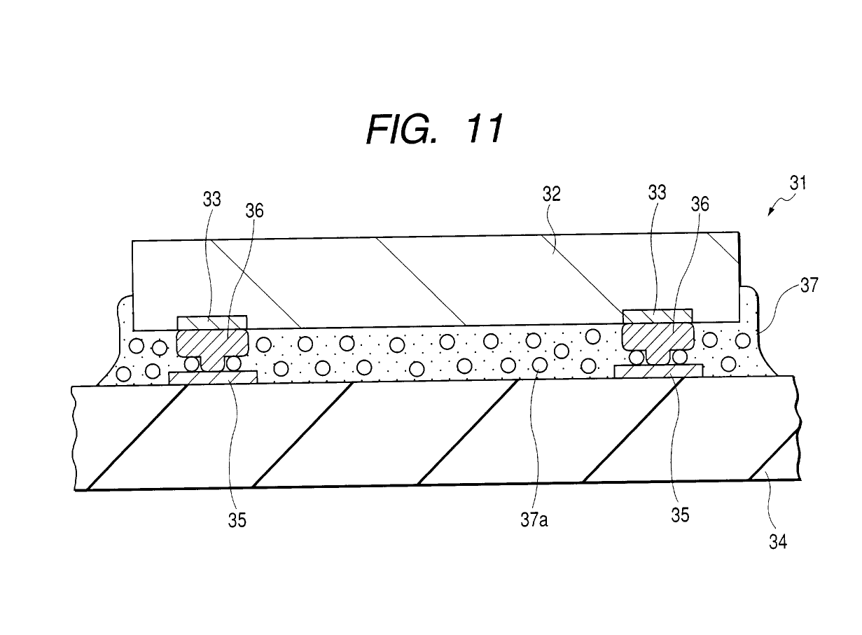

FIG. 11 is a schematic sectional view showing a schematic construction of a semiconductor device according to a third embodiment of the present invention.

As shown in FIG. 11, a semiconductor device 31 of this third embodiment has a construction such that a semiconductor chip 32 is mounted on one main surface of a wiring substrate 34 by the ACF mounting method.

Plural electrode pads 33 are arranged on one main surface of the semiconductor chip 32, while on one main surface of the wiring substrate 34 are arranged plural electrode pads 35 correspondingly to the plural electrode pads 33. As connecting means for electrically connecting the electrode pads 33 and 35 with each other there are used, for example, stud bumps 36 formed of Au for example and an anisotropic conductive resin 37. The anisotropic conductive resin 37 is obtained by forming an insulating resin with a large number of conductive particles 37a dispersed therein into a sheet shape. As the insulating resin there is used, for example, a thermosetting epoxy resin. The electric connection between the electrode pads 33 and 35 is effected by the stud bumps and conductive particles 3a contained in the anisotropic conductive resin 37 interposed between the electrode pads.

Mounting of the semiconductor chip 32 is performed by compression-bonding the semiconductor chip with a bonding tool under the application of heat while interposing the anisotropic conductive resin 37 between one main surface of the wiring substrate 34 and one main surface of the semiconductor chip 32.

Also in the semiconductor device 31 thus constructed there can be obtained the same effect as in the previous first embodiment by providing electrode pads for inspection on one main surface of the semiconductor chip 32 and providing electrode pads for inspection on one main surface of the wiring substrate 34 correspondingly to the electrode pads for inspection formed on the semiconductor chip.

(Fourth Embodiment)

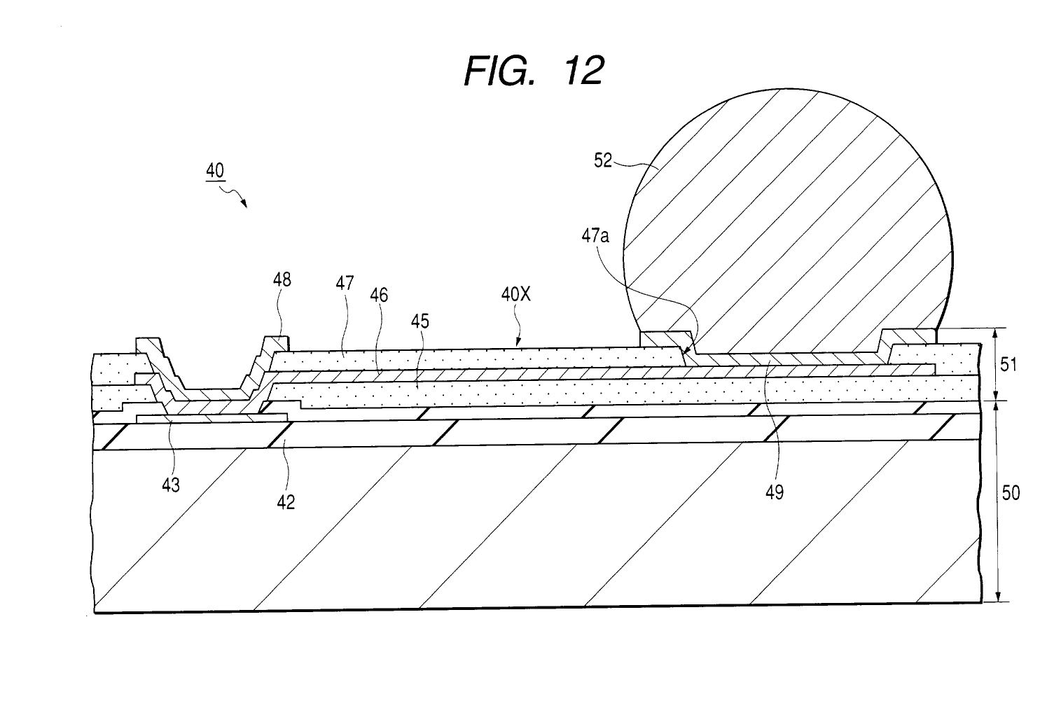

FIG. 12 is a schematic sectional view showing a schematic construction of a semiconductor chip according to a fourth embodiment of the present invention.

As shown in FIG. 12, a semiconductor chip 40 of this embodiment is mainly provided with a semiconductor chip layer 50, a re-wiring layer (pad re-wiring layer) 51 formed on one main surface of the semiconductor chip layer 50, and plural solder bumps 52 arranged on the re-wiring layer 51.

The semiconductor chip layer 50 is mainly provided with a semiconductor substrate 41, a multi-layer interconnection 42 formed by stacking plural stages of insulating layers and wiring layers on one main surface of the semiconductor substrate 41, and a surface protecting film 44 formed so as to cover the multi-layer interconnection 42. For example, the semiconductor substrate 41 is formed of a single crystal silicon, the insulating layers in the multi-layer interconnection 42 are each formed by a silicon oxide film, the wiring layers in the multi-layer interconnection 42 are each formed by an aluminum (A1) or aluminum alloy film, and the surface protecting film 44 is formed by a silicon nitride film.

Centrally of one main surface of the semiconductor chip layer 50 are formed plural electrode pads 43 which are arranged in a long-side direction of one main surface 40X of the semiconductor chip 40. The plural electrode pads 43 are each formed in the top wiring layer of the multi-layer interconnection 42. The top wiring layer of the multilayer interconnection 42 is covered with the surface protecting layer 44 which overlies the top wiring layer. In the surface protecting film 44 are formed apertures to which the surfaces of the electrode pads 43 are exposed.

The re-wiring layer 51 is mainly provided with an insulating layer 45 formed on the surface protecting film 44, plural wiring lines 46 extending on the insulating layer 45, an insulating layer 47 formed on the insulating layer 45 so as to cover the plural wiring lines 46, and plural electrode pads 48 and plural electrode pads 49 both formed on the insulating layer 47.

One ends of the wiring lines 46 are connected electrically and mechanically to the plural electrode pads 43 respectively through apertures formed in the insulating layer 45 and apertures formed in the surface protecting film 44. Opposite ends of approximately half of the plural wiring lines 46 are drawn out to one long side out of two opposed long sides of one main surface 40X of the semiconductor chip 40, while opposite ends of the remaining wiring lines 46 are drawn out to the other long side.

The plural solder bumps 52 arranged on the re-wiring layer 51 are connected respectively to the plural electrode pads 49 electrically and mechanically.

The re-wiring layer 51 is a layer for re-arranging the electrode pads 49 which are wide in arrangement pitch relative to the electrode pads 43 on the semiconductor chip layer 50. The electrode pads 49 on the re-wiring layer 51 are arranged at the same arrangement pitch as that of connections of a wiring substrate on which the semiconductor chip 40 is mounted.

Also in the semiconductor chip 40 thus constructed, the same effect as in the first embodiment can be obtained by providing electrode pads for inspection on one main surface of the semiconductor chip.

(Fifth Embodiment)

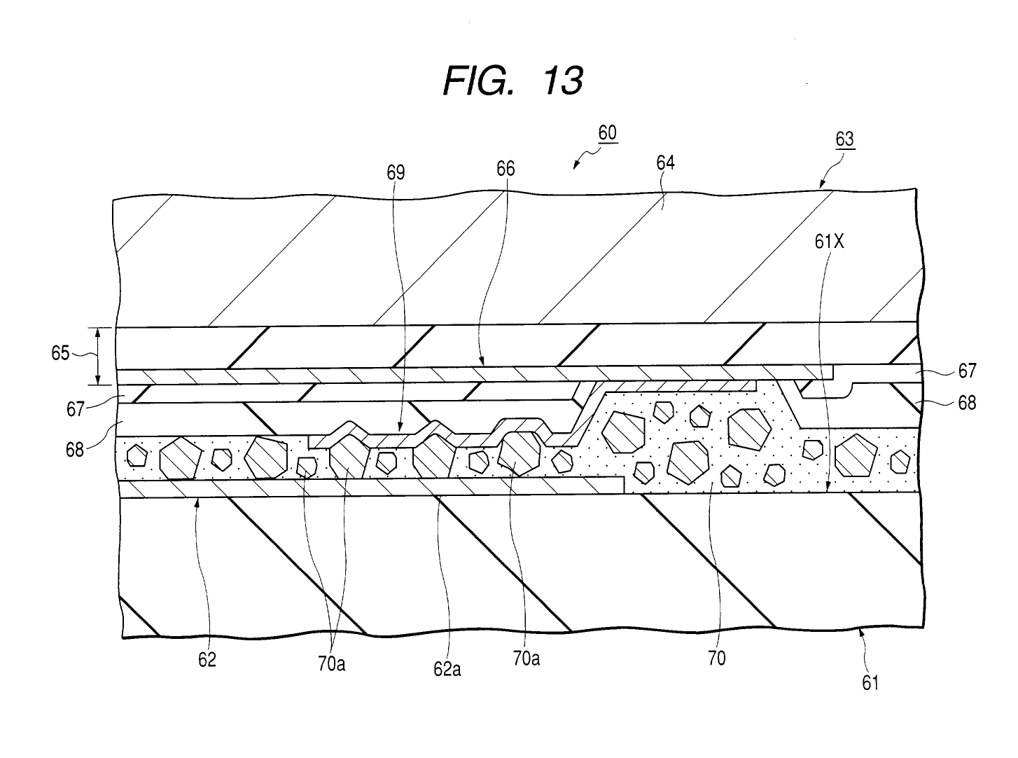

FIG. 13 is a schematic sectional view showing a schematic construction of a semiconductor device according to a fifth embodiment of the present invention.

As shown in FIG. 13, a semiconductor device 60 of this embodiment is constructed such that a semiconductor chip 63 is mounted on one main surface 61X of a wiring substrate 61 by a bumpless mounting method.

On one main surface 61X of the wiring substrate 61 are arranged plural wiring lines 62 and plural electrode pads 62a which are constituted respectively by portions of the plural wiring lines 62.

The semiconductor chip 63 is mainly provided with a semiconductor substrate 64, a multi-layer interconnection 65 formed by a stack of plural stages of insulating layers and wiring layers on one main surface of the semiconductor substrate 64, plural wiring lines 66 formed on the top wiring layer in the multi-layer interconnection 65, a protective film 67 formed so as to cover the wiring lines 66 exclusive of certain portions of the same lines, a soft layer 68 formed on the protective layer 67 exclusive of certain portions of the wiring lines 66, and wiring lines 69 connected at one ends thereof to the certain portions of the wiring lines 66 electrically and drawn out at opposite ends thereof onto the soft layer 68.

As connecting means for electrically connecting the opposite end sides (electrode pads) of the wiring lines 69 with the electrode pads 62a there is used, for example, an anisotropic conductive resin 70. The anisotropic conductive resin 70 is obtained by forming an insulating resin with a large number of conductive particles 70a dispersed therein into a sheet shape. As the insulating resin there is used a thermosetting epoxy resin for example. The electrical connection between the opposite end sides of the wiring lines 69 and the electrode pads 62a is performed by the conductive particles 70a contained in the anisotropic conductive resin 70.

Mounting of the semiconductor chip 63 is performed by compression-bonding the semiconductor chip 63 with a bonding tool under the application of heat while interposing the anisotropic conductive resin 70 between one main surface of the wiring substrate 61 and one main surface of the semiconductor chip 63.

Also in the semiconductor device 60 thus constructed there are obtained the same effect as in the first embodiment by providing electrode pads for inspection on one main surface of the semiconductor chip 63 and providing electrode pads for inspection on one main surface of the wiring substrate 34 correspondingly to the electrode pads for inspection formed on the semiconductor chip.

Although the present invention has been described concretely by way of the above embodiments, it goes without saying that the invention is not limited to those embodiments and that various changes may be made within the scope not departing from the gist of the invention.

The following is a brief description of effects obtained by typical inventions disclosed herein.

According to the present invention, in a semiconductor device which adopts the face down mounting method, it is possible to check the state of continuity between electrode pads formed on a semiconductor chip and electrode pads formed on a wiring substrate.

According to the present invention, it is possible to reduce the cost of a semiconductor device which adopts the face down mounting method.

What is claimed is:

1. A semiconductor device comprising:
a semiconductor chip having a plurality of first electrode pads arranged on one main surface thereof and a first electrode pad for inspection disposed on the one main surface;
a wiring substrate having a plurality of second electrode pads arranged on one main surface thereof correspondingly to the plural first electrode pads and a second electrode pad for inspection disposed on the one main surface correspondingly to the first electrode pad for inspection; and
connecting means interposed between the plural first electrode pads/the first electrode pad for inspection and the plural second electrode pads/the second electrode pad for inspection to provide electrical connections therebetween.

2. A semiconductor device according to claim 1, further comprising a third electrode pad for inspection connected electrically to the first electrode pad for inspection and a fourth electrode pad for inspection connected electrically to the second electrode pad for inspection,
wherein the third and fourth electrode pads for inspection are formed on the wiring substrate.

3. A semiconductor device according to claim 2, wherein the third and fourth electrode pads for inspection are arranged on the one main surface of the wiring substrate and periphery of the semiconductor chip.

4. A semiconductor device according to claim 2, wherein the first, second, third, and fourth electrode pads for inspection are connected in series.

5. A semiconductor device according to claim 2, wherein the first, second, third, and fourth electrode pads for inspection are electrically isolated from the plural first and second electrode pads.

6. A semiconductor device according to claim 1,
wherein the one main surface of the semiconductor chip is formed in a quadrangular shape, and
wherein the first electrode pad for inspection is disposed at a corner of the semiconductor chip.

7. A semiconductor device according to claim 1, wherein the connecting means are conductive bumps.

8. A semiconductor device according to claim 1, wherein the connecting means are constituted by an anisotropic conductive resin comprising an insulating resin and a plurality of conductive particles mixed therein.

9. A semiconductor device according to claim 1, wherein the connecting means comprise conductive bumps and an anisotropic conductive resin comprising an insulating resin and a plurality of conductive particles mixed therein.

10. A semiconductor device according to claim 1, wherein the wiring substrate further has a plurality of third electrode pads on another main surface thereof opposite to the one main surface thereof, the plural third electrode pads being electrically connected to the plural second electrode pads respectively.

11. A semiconductor device according to claim 1,
wherein the semiconductor chip further has an integrated circuit,
wherein the plural first electrode pads are electrically connected to the integrated circuit, and
wherein the first electrode pad for inspection is electrically isolated from the integrated circuit.

12. A semiconductor device comprising:
a semiconductor chip having a plurality of first electrode pads arranged on one main surface thereof and first and second electrode pads for inspection, the first and second electrode pads for inspection being arranged on the one main surface and connected with each other electrically;
a wiring substrate having a plurality of second electrode pads arranged on one main surface thereof correspondingly to the plural first electrode pads, a third electrode pad for inspection disposed on the one main surface correspondingly to the first electrode pad for inspection, and a fourth electrode pad for inspection disposed on the one main surface correspondingly to the second electrode pad for inspection; and
connecting means interposed between the plural first electrode pads/the first and second pads for inspection and the plural second electrode pads/the third and fourth electrode pads for inspection to provide electrical connections therebetween.

13. A semiconductor device according to claim 12, further comprising a fifth electrode pad for inspection connected electrically to the third electrode pad for inspection and a sixth electrode pad for inspection connected electrically to the fourth electrode pad for inspection,
wherein the fifth and sixth electrode pads for inspection are disposed on the wiring substrate.

14. A semiconductor device according to claim 13, wherein the fifth and sixth electrode pads for inspection are arranged on the one main surface of the wiring substrate and periphery of the semiconductor chip.

15. A semiconductor device according to claim 13, wherein the first to sixth electrode pads for inspection are connected in series.

16. A semiconductor device according to claim 13, wherein the first to sixth electrode pads for inspection are electrically isolated from the plural first and second electrode pads.

17. A semiconductor device according to claim 12,
wherein the one main surface of the semiconductor chip is formed in a quadrangular shape, and
wherein the first and second electrode pads for inspection are arranged at corners of the semiconductor chip.

18. A semiconductor device according to claim 12, wherein the connecting means are conductive bumps.

19. A semiconductor device according to claim 12, wherein the connecting means are constituted by an anisotropic conductive resin comprising an insulating resin and a plurality of conductive particles mixed therein.

20. A semiconductor device according to claim 12, wherein the connecting means comprise conductive bumps and an anisotropic conductive resin comprising an insulating resin and a plurality of conductive particles mixed therein.

21. A semiconductor device according to claim 12, wherein the wiring substrate further has a plurality of third electrode pads on another main surface thereof opposite to the one main surface thereof, the plural third electrode pads being electrically connected to the plural second electrode pads respectively.

22. A semiconductor device according to claim 12,
wherein the semiconductor chip further has an integrated circuit,
wherein the plural first electrode pads are connected to the integrated circuit electrically, and
wherein the first and second electrode pads for inspection are electrically isolated from the integrated circuit.

23. A semiconductor device comprising:
a semiconductor chip having a plurality of first electrode pads arranged on one main surface thereof, first and second electrode pads for inspection arranged on the one main surface and connected to each other electrically, and third and fourth electrode pads for inspection arranged on the one main surface and connected to each other electrically;
a wiring substrate having a plurality of second electrode pads arranged on one main surface thereof correspondingly to the plural first electrode pads, fifth and sixth electrode pads for inspection arranged on the one main surface correspondingly to the first and second electrode pads for inspection and connected to each other electrically, a seventh electrode pad for inspection disposed on the one main surface correspondingly to the third electrode pad for inspection and connected electrically to the sixth electrode pad for inspection, and an eighth electrode pad for inspection disposed on the one main surface correspondingly to the fourth electrode pad for inspection and connected electrically to the seventh electrode pad for inspection;
connecting means interposed between the plural first electrode pads/the first to fourth electrode pads for inspection and the plural second electrode pads/the fifth to eighth electrode pads for inspection to provide electrical connections therebetween.

24. A semiconductor device according to claim 23, further comprising a ninth electrode pad for inspection connected electrically to the fifth electrode pad for inspection and a tenth electrode pad for inspection connected electrically to the eighth electrode pad for inspection,
wherein the ninth and tenth electrode pads for inspection are formed on the wiring substrate.

25. A semiconductor device according to claim 24, wherein the ninth and tenth electrode pads for inspection are arranged on the one main surface of the wiring substrate and periphery of the semiconductor chip.

26. A semiconductor device according to claim 24, wherein the first to tenth electrode pads for inspection are connected in series.

27. A semiconductor device according to claim 24, wherein the first to tenth electrode pads for inspection are electrically isolated from the plural first and second electrode pads.

28. A semiconductor device according to claim 24, wherein the one main surface of the semiconductor chip is formed in a quadrangular shape,
wherein first and second electrode pads for inspection are arranged at a first corner of the semiconductor chip, and
wherein the third and fourth electrode pads for inspection are arranged at a second corner opposed to the first corner of the semiconductor chip.

29. A semiconductor device according to claim 23, wherein the connecting means are conductive bumps.

30. A semiconductor device according to claim 23, wherein the connecting means are constituted by an anisotropic conductive resin comprising an insualting resin and a plurality of conductive particles mixed therein.

31. A semiconductor device according to claim 23, wherein the connecting means comprise conductive bumps and an anisotropic conductive resin comprising an insulating resin and a plurality of conductive particles mixed therein.

32. A semiconductor device according to claim 23, wherein the wiring substrate further has a plurality of third electrode pads on another main surface thereof opposite to the one main surface thereof, the plural third electrode pads being electrically connected to the plural second electrode pads respectively.

33. A semiconductor device according to claim 23,
wherein the semiconductor chip further has an integrated circuit, the plural first electrode pads are connected to the integrated circuit electrically, and
wherein the first to fourth electrode pads for inspection are electrically isolated from the integrated circuit.

34. A semiconductor device comprising:
first and second semiconductor chips each having a plurality of first electrode pads arranged on one main surface thereof and first and second electrode pads for inspection arranged on the one main surface and connected to each other electrically;
a wiring substrate having a plurality of second electrode pads arranged on one main surface thereof correspondingly to the plural first electrode pads, a third electrode pad for inspection disposed on the one main surface correspondingly to the first electrode pad for inspection disposed on the first semiconductor chip, a fourth electrode pad for inspection disposed on the one main surface correspondingly to the second electrode pad for inspection disposed on the first semiconductor chip, a fifth electrode pad for inspection disposed on the one main surface correspondingly to the first electrode pad for inspection disposed on the second semiconductor chip and connected electrically to the fourth electrode pad for inspection, and a sixth electrode pad for inspection disposed on the one main surface correspondingly to the second electrode pad for inspection disposed on the second semiconductor chip; and
connecting means interposed between the plural first electrode pads/the first and second electrode pads for inspection on the first semiconductor chip/the first and second electrode pads for inspection on the second semiconductor chip and the plural second electrode pads/the third to sixth electrode pads for inspection to provide electrical connections therebetween.

35. A semiconductor device according to claim 34, further comprising a seventh electrode pad for inspection connected electrically to the third electrode pad for inspection and an eighth electrode pad for inspection connected electrically to the sixth electrode pad for inspection and isolated electrically from the seventh electrode pad for inspection,
wherein the seventh and eighth electrode pad are formed on the wiring substrate.

36. A semiconductor device according to claim 35, wherein the first to eighth electrode pads for inspection are connected in series.

37. A method of manufacturing a semiconductor device, comprising the steps of:
(a) providing a semiconductor chip having on one main surface thereof a plurality of first electrode pads and a first electrode pad for inspection, and providing a wiring substrate having on one main surface thereof a plurality of second electrode pads arranged correspondingly to the plural first electrode pads and a second electrode pad for inspection disposed correspondingly to the first electrode pad for inspection;
(b) interposing conductive bumps between the plural first electrode pads/the first electrode pad for inspection and the plural second electrode pads/the second electrode pad for inspection to provide electrical connections therebetween;
(c) applying a voltage between the first and second electrode pads for inspection to check state of continuity between the two; and
(d) filling an insulating resin between the one main surface of the semiconductor chip and the one main surface of the wiring substrate,
wherein the step (c) is carried out after the step (b) and before the step (d).

38. A semiconductor chip having:
a plurality of electrode pads arranged on one main surface of the chip; and
a first electrode pad for inspection and a second electrode pad for inspection which are arranged on the one main surface of the chip and connected to each other electrically.

39. A semiconductor chip according to claim 38, wherein the first and second electrode pads for inspection are electrically isolated from the plural electrode pads.

40. A semiconductor chip according to claim 38, wherein the first and second electrode pads for inspection are electrically connected to each other through an internal wiring line.

41. A semiconductor chip according to claim 38,
wherein the one main surface is formed in a quadrangular shape, and
wherein the first and second electrode pads for inspection are arranged at a corner of the one main surface.

42. A semiconductor chip according to claim 38,
wherein the one main surface is formed in a quadrangular shape, and
wherein the first and second electrode pads for inspection are each arranged at two corners of the one main surface which corners confront each other.

43. A semiconductor chip according to claim 38,
wherein the one main surface is formed in a quadrangular shape, and
wherein the first and second electrode pads for inspection are each arranged at four corners of the one main surface.

44. A semiconductor chip according to claim 38, further having a plurality of conductive bumps arranged respectively on the plural electrode pads and the first and second electrode pads for inspection.
